(19) United States
(12) Patent Application Publication
(10) Pub. No.: US 2026/0255607 A1
(43) Pub. Date: Aug. 27, 2026

(54) NONVOLATILE MEMORY DEVICE, ELECTRONIC APPARATUS INCLUDING THE NONVOLATILE MEMORY DEVICE, METHOD OF MANUFACURING THE NONVOLATILE MEMORY DEVICE

(71) Applicant: Samsung Electronics Co., Ltd., Suwon-si (KR)

(72) Inventors: Seonghun JANG, Suwon-si (KR); Minhyun LEE, Suwon-si (KR); Seokhoon CHOI, Suwon-si (KR); Jinjoo PARK, Suwon-si (KR); Hoseok HEO, Suwon-si (KR)

(73) Assignee: Samsung Electronics Co., Ltd., Suwon-si (KR)

(21) Appl. No.: 19/376,249

(22) Filed: Oct. 31, 2025

(30) Foreign Application Priority Data
Feb. 24, 2025 (KR) 10-2025-0023882

(51) Int. Cl. H10B 43/35; H10B 43/27

(52) U.S. Cl. CPC H10B 43/35; H10B 43/27

(57) ABSTRACT

Provided are a nonvolatile memory device, an electronic apparatus including the nonvolatile memory device, and a method of manufacturing the nonvolatile memory device. The nonvolatile memory device includes a gate stack including gate electrodes and spacers, that are alternately stacked on each other, a channel hole passing through the gate stack, a charge trap layer in the channel hole, a charge tunneling layer in the charge trap layer, and a channel layer in the charge tunneling layer. The charge trap layer includes nanoparticles and a matrix supporting the nanoparticles.

### CROSS-REFERENCE TO RELATED APPLICATION

This application is based on and claims priority under 35 U.S.C. § 119 to Korean Patent Application No. 10-2025-0023882, filed on Feb. 24, 2025, in the Korean Intellectual Property Office, the disclosure of which is incorporated by reference herein in its entirety.

### BACKGROUND

### 1. Field

The disclosure relates to nonvolatile memory devices including nanoparticles, electronic apparatuses including the nonvolatile memory device, and methods of manufacturing the nonvolatile memory device.

### 2. Description of the Related Art

As hard disks are replaced by solid state drives (SSDs), NAND flash memory devices, which are nonvolatile memory devices, are widely used. As nonvolatile memory devices are becoming more compact and/or more highly integrated, vertical NAND flash memory devices in which a plurality of memory cells are stacked in a direction perpendicular to a substrate are under development.

Recently, as higher integration and/or lower power have been desired, interest in improving problems such as relatively high program/erase voltage, smaller memory window, and/or data retention issues has increased.

### SUMMARY

Some example embodiments provide nonvolatile memory devices including nanoparticles in a charge trap layer.

Some example embodiments provide electronic apparatuses including a nonvolatile memory device including nanoparticles in a charge trap layer.

Some example embodiments provide methods of manufacturing a nonvolatile memory device including nanoparticles in a charge trap layer.

Additional aspects will be set forth in part in the description which follows and, in part, will be apparent from the description, or may be learned by practice of the presented example embodiments of the disclosure.

According to an example embodiment of the disclosure, a nonvolatile memory device includes a gate stack including gate electrodes and spacers, the gate electrodes and the spacers being alternately stacked on each other, a channel hole passing through the gate stack, a charge trap layer in the channel hole, a charge tunneling layer in the charge trap layer, and a channel layer in the charge tunneling layer, wherein the charge trap layer includes a first surface facing the gate stack and a second surface facing the channel layer, the charge trap layer includes nanoparticles and a matrix supporting the nanoparticles, and the nanoparticles are spaced apart from the first surface and come into contact with the second surface.

The nanoparticles may have a shape that protrudes convexly from the second surface toward the first surface.

The nanoparticles may have a shape in which a width changes as a distance from the second surface increases.

An area of a surface where the nanoparticles come into contact with the charge tunneling layer may be less than an area of a surface where the nanoparticles do not come into contact with the charge tunneling layer.

An area of a surface where the matrix comes into contact with the charge tunneling layer may be less than an area of a surface where the matrix does not come into contact with the charge tunneling layer.

An area of a surface where the nanoparticles come into contact with the charge tunneling layer may be greater than an area of a surface where the matrix comes into contact with the charge tunneling layer.

A maximum width of a surface where the nanoparticles come into contact with the charge tunneling layer may be within a range of 2 nm to 10 nm.

The nanoparticles may include a material having a lower band gap than the matrix and lower surface energy than the matrix.

The nanoparticles may include at least one of titanium oxide, vanadium oxide, hafnium oxide, zirconium oxide, cadmium oxide, zinc oxide, or chromium oxide.

The matrix may include at least one of silicon oxide, silicon oxynitride, aluminum oxide, or aluminum oxynitride.

According to an example embodiment of the disclosure, an electronic apparatus includes a memory device and a memory controller configured to control the memory device to perform at least one of reading data from the memory device or writing data to the memory device, wherein the memory device includes a gate stack including gate electrodes and spacers, the gate electrodes and the spacers being alternately stacked on each other, a channel hole passing through the gate stack, a charge trap layer in the channel hole, a charge tunneling layer in the charge trap layer, and a channel layer in the charge tunneling layer, and wherein the charge trap layer includes a first surface facing the gate stack and a second surface facing the channel layer, the charge trap layer includes nanoparticles and a matrix supporting the nanoparticles, and the nanoparticles are spaced apart from the first surface and come into contact with the second surface.

According to an example embodiment of the disclosure, a method of manufacturing a nonvolatile memory device includes alternately stacking spacers and sacrificial layers on a substrate, forming a channel hole to pass through the spacers and the sacrificial layers, forming a preliminary layer inside the channel hole, forming a charge trap layer by phase separation into nanoparticles and a matrix through heat treatment on the preliminary layer, forming a charge tunneling layer in the charge trap layer, forming a channel layer in the charge tunneling layer, removing the sacrificial layers, and forming gate electrodes at positions where the sacrificial layers have been removed, wherein the charge trap layer includes a first surface facing the gate electrodes and a second surface facing the channel layer, and the nanoparticles are spaced apart from the first surface and come into contact with the second surface.

The nanoparticles and the matrix may be formed simultaneously in the charge trap layer, and the phase separation may be performed within a temperature range of 900° C. to 1,300° C.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1 is a cross-sectional view schematically illustrating a nonvolatile memory device according to an example embodiment;

FIG. 2 is a cross-sectional view taken along line A-A′ of FIG. 1;

FIGS. 3 and 4 are transmission electron microscope (TEM) images of a charge trap layer of a nonvolatile memory device according to an example embodiment;

FIG. 5A illustrates a nonvolatile memory device in which nanoparticles have irregular shapes, according to an example embodiment;

FIG. 5B illustrates an example in which nanoparticles have a shape in which a width increases and then decreases as a distance from a second surface increases, according to an example embodiment;

FIG. 6 is a diagram for describing an operational effect of a nonvolatile memory device according to an example embodiment;

FIGS. 7, 8, 9, 10, and 11 illustrate nonvolatile memory devices in which nanoparticles are modified;

FIGS. 12A to 12I illustrate a method of manufacturing a nonvolatile memory device, according to an example embodiment;

FIGS. 13A and 13B are diagrams for describing a method of forming nanoparticles having a core-shell structure;

FIGS. 14A and 14B are diagrams for describing another method of forming nanoparticles;

FIG. 15 illustrates a circuit diagram including a vertical nonvolatile memory device according to an example embodiment;

FIG. 16 is a schematic block diagram of a display driver integrated circuit (IC) (DDI) and a display device including the DDI, according to an example embodiment;

FIG. 17 is a block diagram of an electronic apparatus according to an example embodiment;

FIG. 18 is a block diagram of an electronic apparatus according to an example embodiment;

FIG. 19 is a conceptual diagram schematically illustrating a device architecture applicable to an electronic apparatus, according to an example embodiment; and

FIG. 20 is a conceptual diagram schematically illustrating a device architecture applicable to an electronic apparatus, according to another example embodiment.

### DETAILED DESCRIPTION

Reference will now be made in detail to example embodiments, examples of which are illustrated in the accompanying drawings, wherein like reference numerals refer to like elements throughout. In this regard, the present example embodiments may have different forms and should not be construed as being limited to the descriptions set forth herein. Accordingly, the example embodiments are merely described below, by referring to the figures, to explain aspects. As used herein, the term “and/or” includes any and all combinations of one or more of the associated listed items. Expressions such as “at least one of,” “one of,” “one or more of,” “any one of,” and “at least one selected from” when preceding a list of elements, modify the entire list of elements and do not modify the individual elements of the list. Thus, for example, both “at least one of A, B, or C” and “at least one of A, B, and C” mean either A, B, C, or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hereinafter, nonvolatile memory devices, electronic apparatuses including the nonvolatile memory device, and methods of manufacturing the nonvolatile memory device, according to various example embodiments, are described in detail with reference to the accompanying drawings. In the following drawings, the same reference numerals denote the same elements, and the size of each element in the drawings may be exaggerated for clarity and convenience of explanation. While the terms such as “first” and “second” may be used to describe various elements, such elements should not be limited by these terms. These terms are only used to distinguish one element from another.

The singular forms as used herein are intended to include the plural forms as well unless the context clearly indicates otherwise. It will be understood that the terms “comprise,” “include,” or “have” as used herein specify the presence of stated elements, but do not preclude the presence or addition of one or more other elements. Also, sizes or thicknesses of elements in the drawings may be exaggerated for clarity of explanation. Also, the expression “a certain material layer is present on a substrate or another layer” may mean that the material layer may be present in direct contact with the substrate or the other layer, and another third layer may intervene therebetween. Materials constituting layers in the following example embodiments are only examples, and other materials may be used.

Also, the terms such as “unit” and “module” described in the specification mean units that process at least one function or operation, and may be implemented as hardware, software, or a combination of hardware and software.

Specific implementations described in the present example embodiments are only examples and do not limit the scope of the disclosure in any way. For the sake of conciseness of the specification, descriptions of conventional electronic components, control systems, software, and other functional aspects of the systems may be omitted. In addition, connecting lines or connecting members illustrated in the drawings are intended to represent example functional connections and/or physical or circuit connections. In an actual device, it may appear as a variety of alternative or additional functional, physical, or circuit connections.

The use of the term “the” and similar demonstratives may correspond to both the singular and the plural.

Operations constituting methods may be performed in any suitable order unless otherwise indicated herein or otherwise clearly contradicted by context. Also, the use of all illustrations or illustrative terms (for example, etc.) in the example embodiments is simply to describe the technical ideas in detail, and the scope of the disclosure is not limited by the illustrations or illustrative terms unless they are limited by claims.

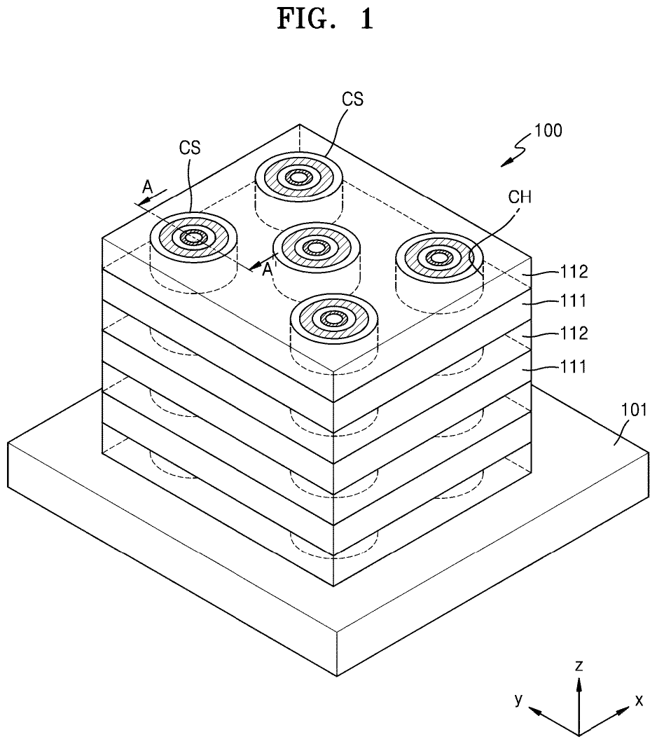

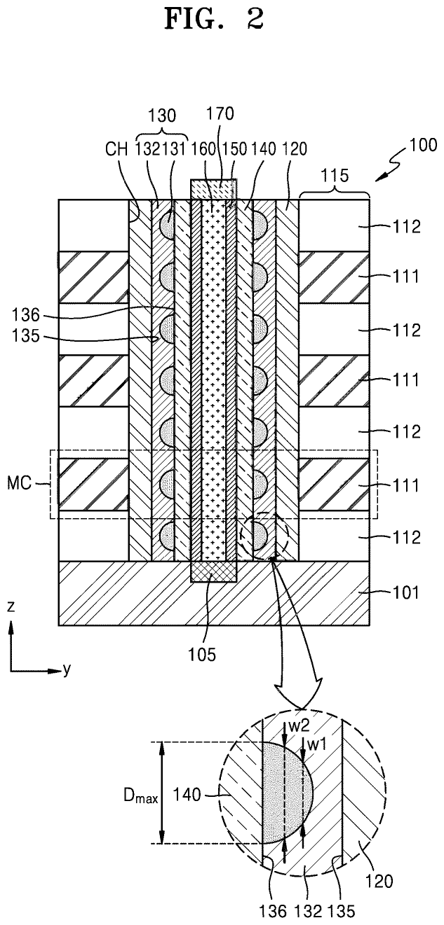

Referring to FIG. 1, a nonvolatile memory device 100 may include a plurality of cell strings CS arranged on a substrate 101. Each of the cell strings CS may be arranged to extend in a direction (a Z-axis direction) perpendicular to the substrate 101. The cell strings CS may be arranged on the substrate 101 in various forms. Gate electrodes 111 and spacers 112 may be alternately stacked in a direction (the Z-axis direction) perpendicular to the substrate 101. A channel hole CH may be provided to pass through a gate stack (see 115 of FIG. 2) of the gate electrodes 111 and the spacers 112 in a direction (the Z-axis direction) perpendicular to the substrate 101. The channel hole CH may be formed to have, for example, a circular cross-section. However, the cross-sectional shape of the channel hole CH is not limited thereto.

A region excluding the gate electrodes 111 and the spacers 112 in the cell string CS may have a stacked structure of a plurality of cylindrical shells in the channel hole CH. However, the structure of the cell string CS is not limited thereto, and the cell string CS may have other shapes and structures.

Referring to FIG. 2, a charge trap layer 130 may be provided inside the channel hole CH, a charge tunneling layer 140 may be provided in the charge trap layer 130, and a channel layer 150 may be provided in the charge tunneling layer 140. A pillar 160 may be provided in the channel layer 150. A charge barrier layer 120 may be provided between the channel hole CH (e.g., a boundary of the channel hole CH) and the charge trap layer 130.

The charge trap layer 130 may include nanoparticles 131 and a matrix 132 supporting the nanoparticles 131. The charge trap layer 130 may include a first surface 135 facing the gate stack 115 and a second surface 136 facing the channel layer 150. The nanoparticles 131 may be spaced apart from the first surface 135 and come into contact with the second surface 136. For convenience of explanation, the first surface 135 may be described as a surface facing the gate electrode 111. The nanoparticles 131 may be spaced apart along the second surface 136 and arranged in a row. Referring to FIG. 2, the nanoparticles 131 may come into contact with the charge tunneling layer 140 and be spaced apart from the charge barrier layer 120.

The cell string CS may include a plurality of memory cells MC stacked in a direction (the Z-axis direction) perpendicular to the substrate 101. The memory cell MC may be a basic unit cell that writes and erases data.

The substrate 101 may include a single-crystal silicon substrate, a compound semiconductor substrate, or a silicon-on-insulator (SOI) substrate, but example embodiments of the present disclosure are not limited thereto. In addition, the substrate 101 may further include, for example, doped impurity regions, electronic elements such as transistors, peripheral circuits that select and control the memory cells MC to store data, and the like.

The pillar 160 may include, for example, silicon oxide or air, but example embodiments of the present disclosure are not limited thereto. The channel layer 150, the charge tunneling layer 140, and the charge trap layer 130 may each be provided to extend perpendicular to the substrate 101 and may be shared by the memory cells MC.

The channel layer 150 may include a semiconductor material. The channel layer 150 may include, for example, Si, Ge, SiGe, or a Group III-V semiconductor. In addition, the channel layer 150 may include, for example, an oxide semiconductor, a nitride semiconductor, an oxynitride semiconductor, a two-dimensional (2D) semiconductor material, quantum dots, or an organic semiconductor. The oxide semiconductor may include, for example, InGaZnO. The 2D semiconductor material may include, for example, transition metal dichalcogenide (TMD) or graphene, and the quantum dots may include colloidal quantum dots (QDs), nanocrystal structures, etc. The 2D semiconductor material may refer to a semiconductor material having a 2D crystal structure and may have a monolayer or multilayer structure. The 2D semiconductor material may have improved electrical properties and may maintain relatively high mobility without changing properties even when the thickness of the 2D semiconductor material is reduced to the nanoscale. Accordingly, the 2D semiconductor material may be applied to various devices. Each layer constituting the 2D semiconductor material may have an atomic-level thickness. The channel layer 150 may include, for example, 1-10 layers of 2D semiconductor material layers. However, example embodiments of the present disclosure are not limited thereto.

The 2D semiconductor material may include, for example, at least one of graphene, black phosphorus, or TMD. The graphene is a material in which carbon atoms are two-dimensionally bonded to form a hexagonal honeycomb structure. Compared to silicon (Si), the graphene may have an advantage of relatively high electrical mobility, relatively good thermal properties, improved chemical stability, and/or a relatively large surface area. The black phosphorus is a material in which black phosphorous atoms are two-dimensionally bonded to each other.

The TMD may be represented by, for example, MX₂, wherein M represents a transition metal and X represents a chalcogen element. For example, M may include Mo, W, Nb, V, Ta, Ti, Zr, Hf, Tc, or Re, and X may include S, Se, or Te. Accordingly, the TMD may include, for example, MoS₂, MoSe₂, MoTe₂, WS₂, WSe₂, WTe₂, ZrS₂, ZrSe₂, HfS₂, HfSe₂, NbSe₂, or ReSe₂.

In some example embodiments, the 2D semiconductor material may include CuS, which is a compound of a transition metal Cu and a chalcogen element S. In some example embodiments, the 2D semiconductor material may be a chalcogenide material including a non-transition metal. The non-transition metal may include, for example, Ga, In, Sn, Ge, Pb, etc. In this case, the 2D semiconductor material may include a compound of a non-transition metal, such as Ga, In, Sn, Ge, or Pb, and a chalcogen element, such as S, Se, or Te. For example, the 2D semiconductor material may include SnSe₂, GaS, GaSe, GaTe, GeSe, In₂Se₃, InSnS₂, etc. However, the materials described above are only examples, and other materials may also be used as the 2D semiconductor material.

The channel layer 150 may further include a dopant. The dopant may include a p-type dopant or an n-type dopant. The p-type dopant may include a Group III element, such as B, Al, Ga, or In, and the n-type dopant may include a Group V element, such as P, As, or Sb.

The charge tunneling layer 140 is a layer in which charge tunneling occurs. The charge tunneling layer 140 may include, for example, silicon oxide or metal oxide, but example embodiments of the present disclosure are not limited thereto.

The gate electrodes 111 may be stacked spaced apart from each other in a direction perpendicular to the substrate 101, and the spacers 112 may be provided between the gate electrodes 111, respectively. The spacer 112 may include an insulating material and may separate the gate electrodes 111 so that the gate electrodes 111 may be driven independently in units of the memory cells MC. Although FIG. 1 does not illustrate a source electrode and a drain electrode, FIG. 2 illustrates a source electrode 105 and a drain electrode 170. The source electrode 105 may be provided below the channel layer 150, and the drain electrode 170 may be provided above the channel layer 150. The drain electrode 170 may be connected to a bit line, and the gate electrode 111 may be connected to a word line.

Although FIG. 2 illustrates that the source electrode 105 is connected to each of the cell strings CS, the source electrode 105 may also be commonly connected to the cell strings CS.

Referring to the overall structure, the channel layer 150 may surround the side surface of the pillar 160, the charge tunneling layer 140 may surround the side surface of the channel layer 150, and the charge trap layer 130 may surround the side surface of the charge tunneling layer 140.

The gate electrodes 111 and the spacers 112 may be alternately arranged in a direction perpendicular to the substrate 101, and the charge barrier layer 120 may be provided between the charge trap layer 130 and the gate stack 115.

A channel corresponding to the gate electrode 111 may be formed in the channel layer 150 between the source electrode 105 and the drain electrode 170. When a certain voltage is applied to the gate electrode 111 in each of the memory cells MC, charges flowing between the source electrode 105 and the drain electrode 170 within the channel layer 150 corresponding to the gate electrode 111 may pass through the charge tunneling layer 140 and be trapped within the charge trap layer 130, and thus, information may be stored.

The gate electrode 111 may control the corresponding channel layer 150, and the word line may be electrically connected to the gate electrode 111. The gate electrode 111 may include a metal material with good electrical conductivity, a conductive oxide, a metal nitride, silicon doped with impurities, or a 2D conductive material. The metal material and the metal nitride may include, for example, Au, Ti, TiN, TaN, W, Mo, WN, Pt, Ni, or any combination thereof. The conductive oxide may include, for example, indium tin oxide (ITO), indium zinc oxide (IZO), indium zinc oxide (IZO), etc. However, this is only an example, and the gate electrode 111 may include various other materials. The spacer 112 may act as a spacer layer for insulation between the gate electrodes 111. The spacer 112 may include, for example, silicon oxide, silicon nitride, a metal organic framework, or boron nitride. The metal organic framework may include a porous solid material synthesized through self-assembly based on a metal node and an organic ligand. The metal organic framework may include, for example, UiO-66 or ZIF-8. The boron nitride may include amorphous BN or amorphous BCN.

The charge barrier layer 120 may perform a barrier function that blocks charge transfer between the charge trap layer 130 and the gate electrode 111. One surface of the charge barrier layer 120 may come into contact with the charge trap layer 130, and another surface of the charge barrier layer 120 may come into contact with the gate electrode 111 and the spacer 112.

The charge trap layer 130 may store introduced charges. The charges (e.g., electrons) existing in the channel layer 150 may be introduced into the charge trap layer 130 by a tunneling effect or the like. The charges introduced into the charge trap layer 130 may be fixed to the charge trap layer 130.

The charge trap layer 130 may include nanoparticles 131 and a matrix 132 supporting the nanoparticles 131. The nanoparticles 131 may include a material having relatively good charge trap properties, and the matrix 132 may include a material having blocking properties for charge transfer. The nanoparticles 131 may have a shape that protrudes convexly from the charge tunneling layer 140 toward the charge barrier layer 120.

The nanoparticles 131 may have a shape, the width of which changes as the distance from the charge tunneling layer 140 increases. The width may represent a width in the stacking direction of the gate electrode 111 and the spacer 112 (e.g., a width in the z direction). The nanoparticles 131 may have a shape, the width of which decreases as the distance from the charge tunneling layer 140 increases. In the nanoparticles 131, a first width W1 at a position relatively far from the second surface 136 may be less than a second width W2 at a position relatively close to the second surface 136 (W1<W2).

However, the shape of the nanoparticles 131 is not limited thereto, and the nanoparticles 131 may have a shape, the width of which increases and then decreases as the distance from the charge tunneling layer 140 increases.

The nanoparticles 131 may come into surface contact with the charge tunneling layer 140. A maximum width Dₘₐₓ of the surface where the nanoparticles 131 come into contact with the charge tunneling layer 140 may be within a range of about 2 nm to about 10 nm. The maximum width Dₘₐₓ is limited based on the maximum width Dₘₐₓ at the contact surface because the surface where the nanoparticles 131 come into contact with the charge tunneling layer 140 is not a circle with a constant diameter but may have various cross-sectional shapes. In addition, the area of the surface where the nanoparticles 131 come into contact with the charge tunneling layer 140 may be less than the area of the surface where the nanoparticles 131 do not come into contact with the charge tunneling layer 140. The area of the surface where the matrix 132 comes into contact with the charge tunneling layer 140 may be less than the area of the surface where the matrix 132 does not come into contact with the charge tunneling layer 140.

The nanoparticles 131 may have a lower band gap than the matrix 132. The nanoparticles 131 may include a material having lower surface energy than the matrix 132.

The nanoparticles 131 may include at least one of titanium oxide, vanadium oxide, hafnium oxide, zirconium oxide, cadmium oxide, zinc oxide, or chromium oxide. The matrix 132 may include at least one of silicon oxide, silicon oxynitride, aluminum oxide, or aluminum oxynitride.

The nanoparticles 131 may have, for example, a truncated spherical shape, a truncated elliptical shape, a rod shape, etc. The nanoparticles 131 may have a nano size. The size of the nanoparticles 131 may refer to an average width or an average thickness of the nanoparticles 131. The nanoparticles 131 may have a size of about 1 nm to about 20 nm. The nanoparticles 131 may have a size of about 2 nm to about 18 nm. The distance between the neighboring nanoparticles 131 may be about 1 nm to about 25 nm. The distance may represent the shortest distance between the surfaces of the neighboring nanoparticles 131.

The charge trap layer 130 may be formed by spinodal decomposition through heat treatment. The spinodal decomposition may occur when formation energy (e.g., a Gibbs free-energy change (ΔG)) due to the mixing of materials forming the charge trap layer 130 at a specific temperature is greater than 0. The shape and size of the nanoparticles 131 may be adjusted according to a heat treatment temperature for a material forming the charge trap layer 130.

The charge barrier layer 120 may reduce or prevent charges from leaking beyond the charge trap layer 130 to the spacers 112 and the gate electrodes 111. The charge barrier layer 120 may include silicon oxide, metal oxide, or metal nitride, but example embodiments of the present disclosure are not limited thereto. The charge barrier layer 120 may include at least one of aluminum oxide (AlO), magnesium oxide (MgO), aluminum nitride (AlN), or gallium nitride (GaN). The charge barrier layer 120 may include, for example, SiO₂ or Al₂O₃.

The charge barrier layer 120 may include a ferroelectric material or an anti-ferroelectric material. The ferroelectric material may have ferroelectricity, in which internal electric dipole moments are aligned to maintain spontaneous polarization even when no electric field is applied from outside. The ferroelectric material may exhibit spontaneous polarization because permanent dipoles are aligned parallel to each other in the same direction. The ferroelectric material may have remnant polarization due to dipoles even in the absence of an external electric field. In addition, the direction of the polarization may be switched on a domain basis by an external electric field. A threshold voltage of the nonvolatile memory device 100 may be changed according to a polarization direction of the ferroelectric material, for example, a direction from the gate electrode 111 toward the channel layer 150, or conversely, a direction from the channel layer 150 toward the gate electrode 111.

The anti-ferroelectric material may include an array of electric dipoles but may have a remnant polarization of zero or close to zero. Because the directions of the adjacent dipoles are opposite in the absence of an electric field and the polarizations thereof cancel out, the overall spontaneous polarization and remnant polarization may be zero or close to zero. However, polarization characteristics and switching characteristics may be exhibited in a state in which an external electric field is applied.

The ferroelectric material may include a hafnium oxide material or an aluminum nitride material. The ferroelectric material may have a structure in which a dopant is inserted into a hafnium oxide-based material or a structure in which a dopant is inserted into an aluminum nitride-based material. When the ferroelectric material is a hafnium oxide-based material, the dopant may be Zr, La, Al, Si, or Y. When the ferroelectric material is an aluminum nitride-based material, the dopant may be B or Sc.

In some example embodiments, the ferroelectric material may include, for example, a ferroelectric material having at least one of a fluorite structure, a perovskite structure, or a wurtzite structure.

The ferroelectric material having a fluorite structure may include, for example, HfO₂ or ZrO₂. HfO₂ or ZrO₂ may have a crystal structure of a tetragonal system or a crystal structure of an orthorhombic system. The crystal structure of the tetragonal system may have anti-ferroelectricity, and the crystal structure of the orthorhombic system may have ferroelectricity. Undoped HfO₂ may have the stable crystal structure of the tetragonal system but may also have the crystal structure of the orthorhombic system according to the grain size. Undoped ZrO₂ may have the stable crystal structure of the tetragonal system. Undoped HfO₂ or ZrO₂ may include, for example, nanoparticles having a grain size of about 1 nm to about 3 nm, but example embodiments of the present disclosure are not limited thereto.

The fluorite-based material may include, for example, HfO₂ or ZrO₂ including a dopant. The dopant may include at least one of, for example, Al, Ga, Co, Ni, Mg, In, La, Y, Nd, Sm, Er, Sr, Ba, Gd, Ge, N, or Si. However, this is only an example. HfO₂ or ZrO₂ including the dopant may have the crystal structure of the tetragonal system with anti-ferroelectricity or the crystal structure of the orthorhombic system with ferroelectricity according to a grain size and/or a doping concentration. As the grain size decreases and the doping concentration increases, the crystal structure of the tetragonal system becomes stabler. As the grain size increases and the doping concentration decreases, the crystal structure of the orthorhombic system becomes stabler.

HfO₂ or ZrO₂ doped with the dopant may include nanoparticles having a larger grain size than the undoped HfO₂ or ZrO₂ described above. For example, HfO₂ or ZrO₂ doped with the dopant may have a grain size of about 4 nm to 7 nm, or 4 nm to 5 nm, but example embodiments of the present disclosure are not limited thereto.

The concentration of the dopant may vary depending on the type of dopant. Fo example, when the dopant is Si, the doping concentration may be about 1 atomic percent (at %) to 5 at %. However, example embodiments of the present disclosure are not limited thereto.

The ferroelectric material having the perovskite structure may include a material having a composition of M¹M²O₃ (M¹M² is a metal element). The perovskite-based material may include, for example, at least one of PbZrO₃, PbTiO₃, BaTiO₃, SrTiO₃, or CaTiO₃. However, example embodiments of the present disclosure are not limited thereto. The perovskite-based material may have the crystal structure of the tetragonal system with anti-ferroelectricity or the crystal structure of the orthorhombic system with ferroelectricity according to the composition ratio of the constituent elements.

The wurtzite-based material may include undoped AlN, GaN, or InN, or may include AlN, GaN, or InN including a dopant. The dopant may include at least one of boron (B) or scandium (Sc). For example, the charge barrier layer 120 may include hafnium zirconium oxide (HfZrO), and Zr/(Hf+Zr) may be within a range of about 20 at % to about 80 at %.

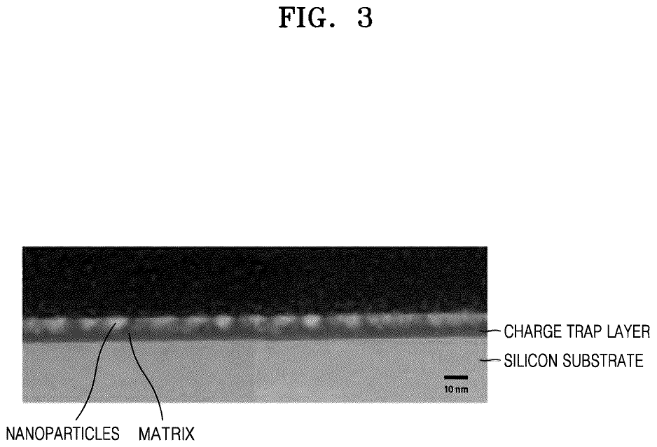

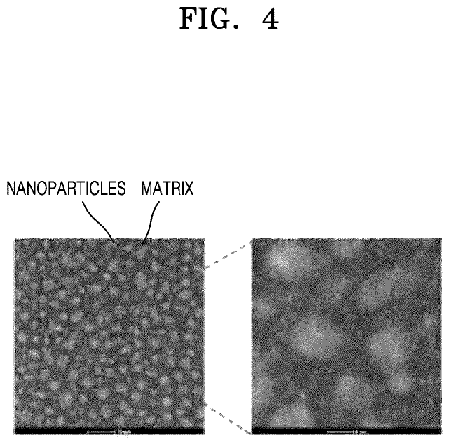

FIG. 3 is a transmission electron microscope (TEM) image of a charge trap layer in which TiO₂ nanoparticles and a SiO₂ matrix are formed on a silicon substrate by phase separation, and FIG. 4 is a planar TEM image of the charge trap layer of FIG. 3. The nanoparticles may be in contact with one surface and spaced apart from another surface. As described below, the nanoparticles and the matrix may be formed by phase separation. FIG. 3 shows that the nanoparticles have a truncated spherical shape as a whole.

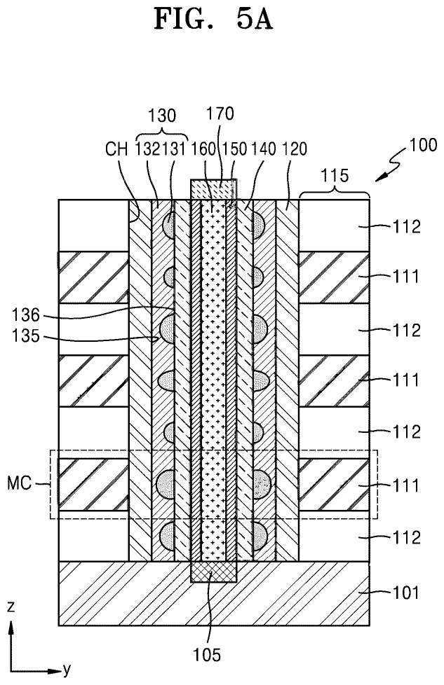

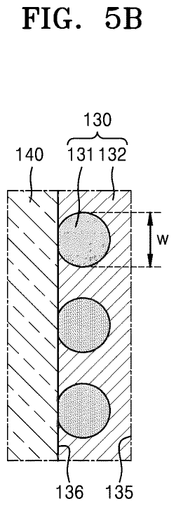

FIG. 5A shows that the nanoparticles 131 have an irregular shape, compared to FIG. 2. The nanoparticles 131 may be in contact with the second surface 136 and spaced apart from the first surface 135 and may have a shape that protrudes convexly from the second surface 136 toward the first surface 135. The nanoparticles 131 may have various sizes and may be arranged in a row.

FIG. 5B illustrates an example in which the nanoparticles 131 have a shape in which a width w increases and then decreases as the distance from the second surface 136 increases, according to an example embodiment. The nanoparticles 131 may have various shapes that protrude while coming into surface contact with the second surface 136.

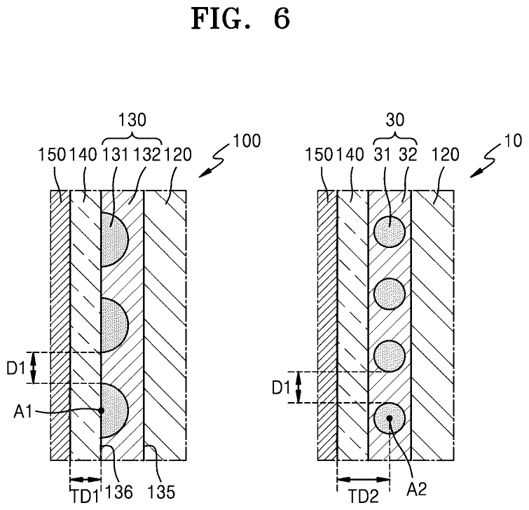

The operational effect of the nonvolatile memory device 100 according to an example embodiment is described with reference to FIG. 6.

FIG. 6 illustrates the nonvolatile memory device 100 according to an example embodiment and a comparative example 10 together. In the nonvolatile memory device 100, the nanoparticles 131 come into contact with the charge tunneling layer 140 and are spaced apart from the charge barrier layer 120. In the comparative example 10, a charge trap layer 30 includes nanoparticles 31 and a matrix 32, and the nanoparticles 31 have approximately a spherical shape and are spaced apart from both interfaces. When a gap D1 between the neighboring nanoparticles 131 in the charge trap layer 130 is equal to a gap D1 between the neighboring nanoparticles 31 in the charge trap layer 30, the volume of the nanoparticles 131 is greater than the volume of the nanoparticles 31 of the comparative example when the volume of the charge trap layer 130 is equal to the volume of the charge trap layer 30. When the volume of the nanoparticles 131 is greater than the volume of the nanoparticles 31, a memory window may be increased.

In addition, when the nanoparticles 131 come into contact with the second surface 136 facing the channel layer 150, a charge centroid region A1 with a relatively high charge trap density may be positioned relatively close to the channel layer 150. The charge centroid region A1 may be positioned approximately at the center point of the sphere. Although FIG. 6 illustrates that the charge centroid region A1 is positioned on the second surface 136, this is only a rough representation for ease of understanding. In the comparative example, a charge centroid region A2 with a relatively high charge trap density of the nanoparticles 31 may be positioned at the center of the nanoparticles 31. A tunneling distance TD1 from the channel layer 150 to the charge centroid region A1 in the nonvolatile memory device 100 is less than a tunneling distance TD2 from the channel layer 150 to the charge centroid region A2 in the comparative example 10. As the tunneling distance decreases, a more threshold voltage change in the channel layer 150 may be induced with fewer charge traps, which may increase a memory window and reduce an operating voltage. In the nonvolatile memory device 100 according to an example embodiment, because the operating voltage is reduced, power consumption may be reduced.

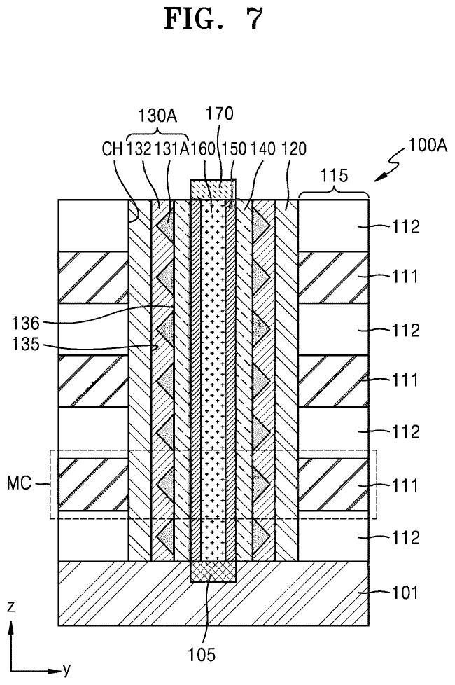

FIG. 7 illustrates an example in which the shape of the nanoparticles 131A is modified, compared to FIG. 2. In FIG. 7, members denoted by the same reference numbers as in FIG. 2 are substantially the same as those described with reference to FIG. 2, and thus, detailed descriptions thereof are omitted herein and the differences are mainly described.

A nonvolatile memory device 100A may include a charge trap layer 130A. The charge trap layer 130A may include nanoparticles 131A and a matrix 132 supporting the nanoparticles 131A. The nanoparticles 131A may be spaced apart from a first surface 135 and come into contact with a second surface 136. The nanoparticles 131A may have a shape protruding from the second surface 136 toward the first surface 135 and may have a triangular cross-section. The nanoparticles 131A may have, for example, a polypyramid structure.

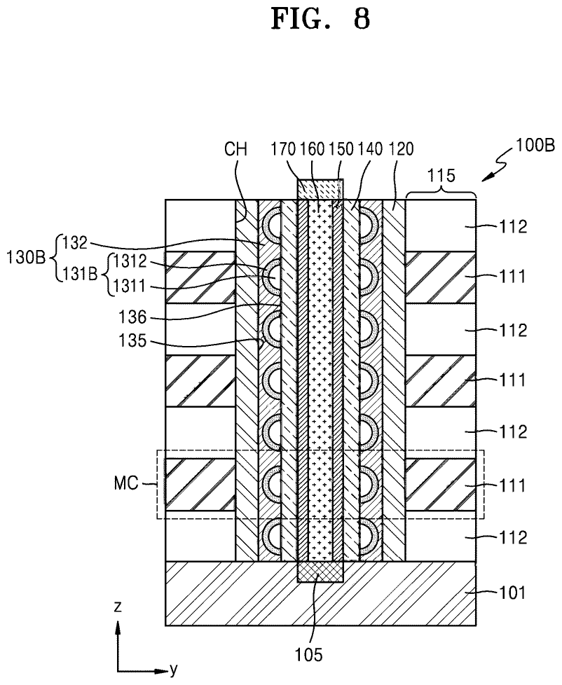

FIG. 8 illustrates a nonvolatile memory device 100B including a charge trap layer 130B, according to another example embodiment.

The nonvolatile memory device 100B may include the charge trap layer 130B. The charge trap layer 130B may include nanoparticles 131B having a core-shell structure and a matrix 132 supporting the nanoparticles 131B. The nanoparticles 131B may include a core 1311 and a shell 1312 surrounding the core 1311. The core 1311 may have a structure that protrudes convexly from a second surface 136 toward a first surface 135. The core 1311 may have, for example, a truncated spherical shape. The shell 1312 may have a spherical shell shape with a portion truncated.

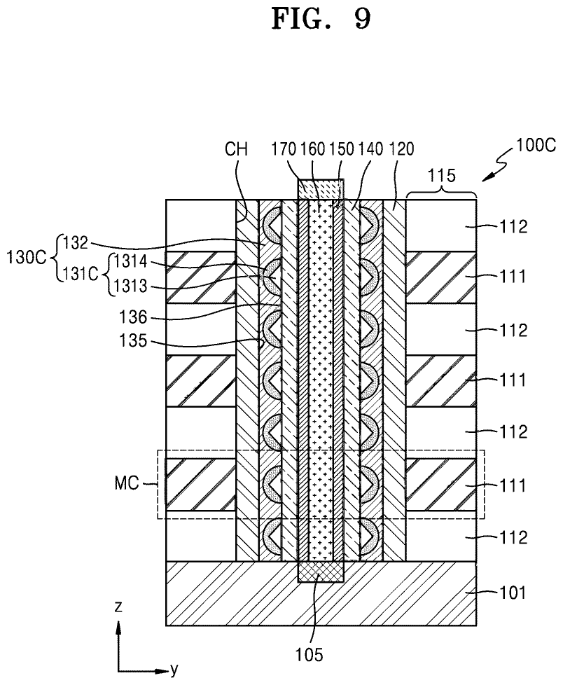

FIG. 9 illustrates a nonvolatile memory device 100C including a charge trap layer 130C, according to another example embodiment.

The nonvolatile memory device 100C may include the charge trap layer 130C. The charge trap layer 130C may include nanoparticles 131C having a core-shell structure and a matrix 132 supporting the nanoparticles 131C. The nanoparticles 131C may include a core 1313 and a shell 1314 surrounding the core 1313. The core 1313 may have a structure that protrudes convexly from a second surface 136 toward a first surface 135. The core 1313 may have, for example, a polypyramid shape. The shell 1314 may cover the core 1313 and may have a spherical shape with a portion of the outer surface truncated.

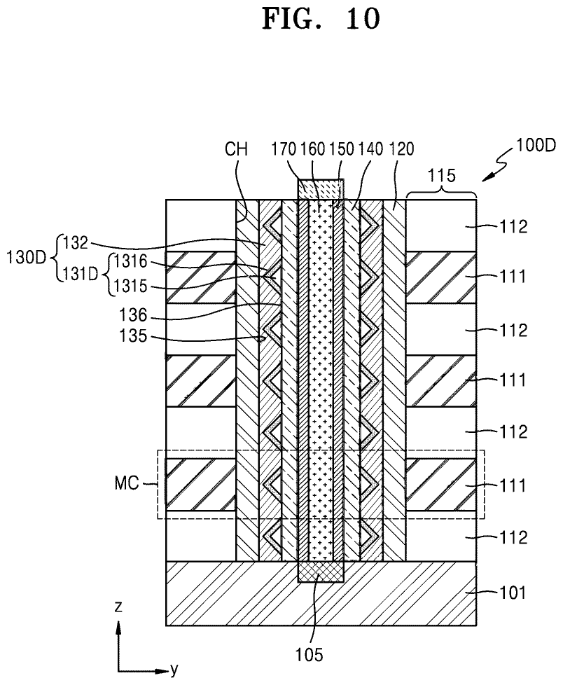

FIG. 10 illustrates a nonvolatile memory device 100D including a charge trap layer 130D, according to another example embodiment.

The nonvolatile memory device 100D may include the charge trap layer 130D. The charge trap layer 130D may include nanoparticles 131D having a core-shell structure and a matrix 132 supporting the nanoparticles 131D. The nanoparticles 131D may include a core 1315 and a shell 1316 surrounding the core 1315. The core 1315 may have a structure that protrudes convexly from a second surface 136 toward a first surface 135. The core 1315 may have, for example, a polypyramid shape. The shell 1316 may cover the core 1315 and may have a polypyramid shape corresponding to the shape of the core 1315.

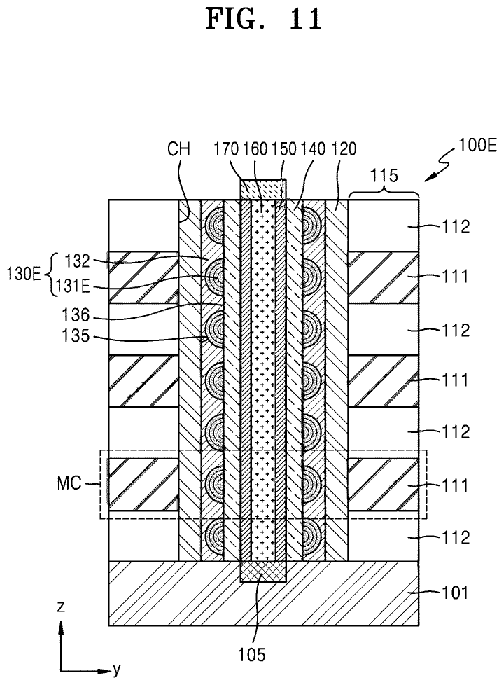

FIG. 11 illustrates a nonvolatile memory device 100E including a charge trap layer 130E, according to another example embodiment.

The nonvolatile memory device 100E may include the charge trap layer 130E. The charge trap layer 130E may include nanoparticles 131E and a matrix 132 supporting the nanoparticles 131E. The nanoparticles 131E may have a gradation distribution in which a charge trap density varies. For example, the nanoparticles 131E may have a structure that protrudes convexly from a second surface 136 toward a first surface 135 and may have a distribution in which a charge trap density decreases from the second surface 136 to the first surface 135. In some example embodiments, the nanoparticles 131E may have a distribution in which a charge trap density decreases radially from the center of an interface where the nanoparticles 131E meet the second surface 136. However, the charge trap density distribution is not limited thereto and may have different charge trap density distributions.

As described above, in the nonvolatile memory devices 100, 100A, 100B, 100C, and 100D according to an example embodiment, the nanoparticles 131, 131A, 131B, 131C, and 131D in the charge trap layers 130, 130A, 130B, 300C, and 300D may come into contact with the second surface 136 facing the channel layer 150 and may be spaced apart from the first surface 135 facing the gate stack 115. Accordingly, the nonvolatile memory devices 100, 100A, 100B, 100C, and 100D according to an example embodiment may have an effect of increasing the memory window and/or reducing the operating voltage. In addition, in the nonvolatile memory devices 100, 100A, 100B, 100C, and 100D according to an example embodiment, electrons may be stored in the structurally isolated nanoparticles 131, 131A, 131B, 131C, and 131D, and thus, lateral charge loss may be effectively reduced.

The nonvolatile memory devices 100, 100A, 100B, 100C, and 100D may include a plurality of memory cells that retain information even when power thereto is cut off and may use the stored information again when power thereto is supplied. The nonvolatile memory devices 100, 100A, 100B, 100C, and 100D may be widely applied to mobile phones, digital cameras, personal digital assistants (PDAs), portable computing devices, etc.

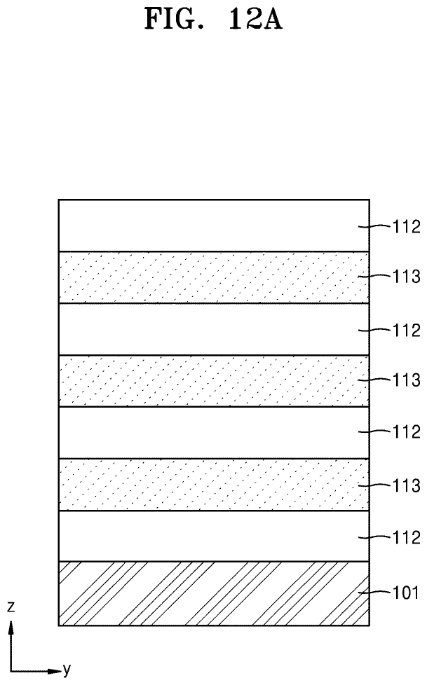

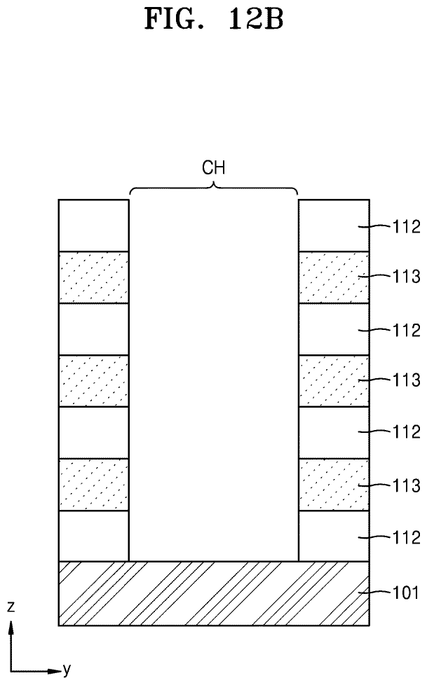

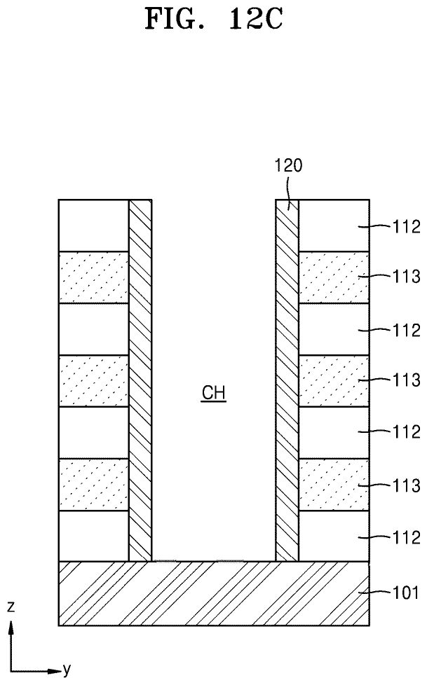

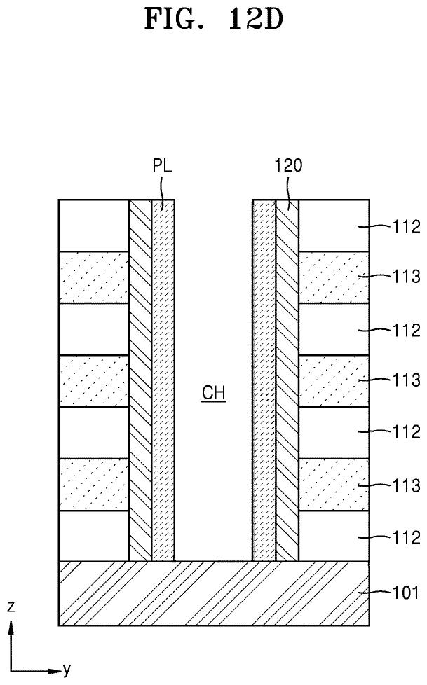

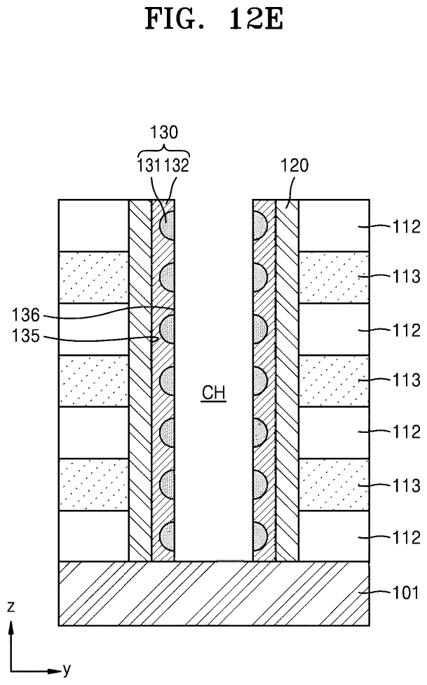

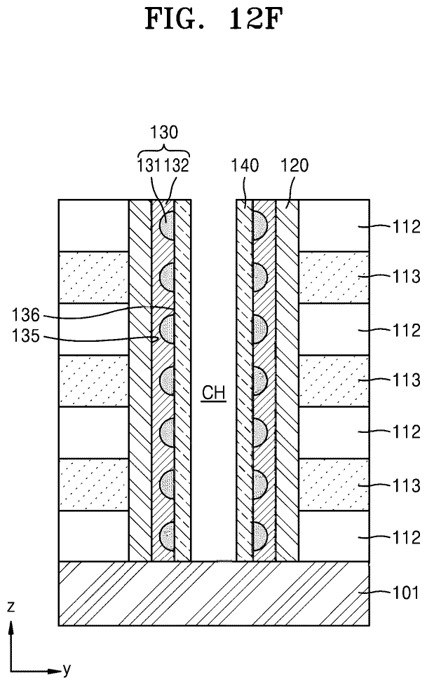

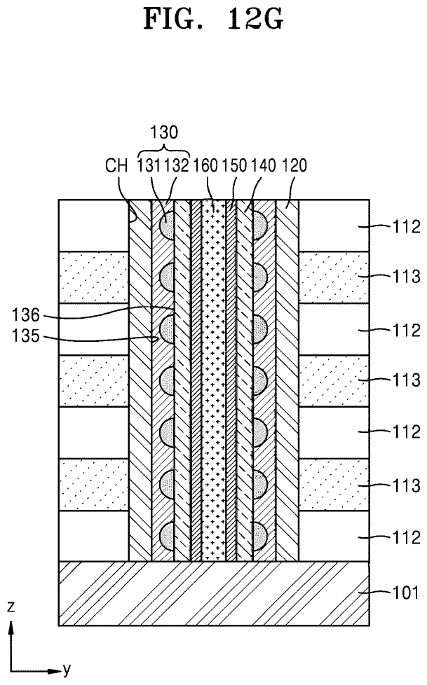

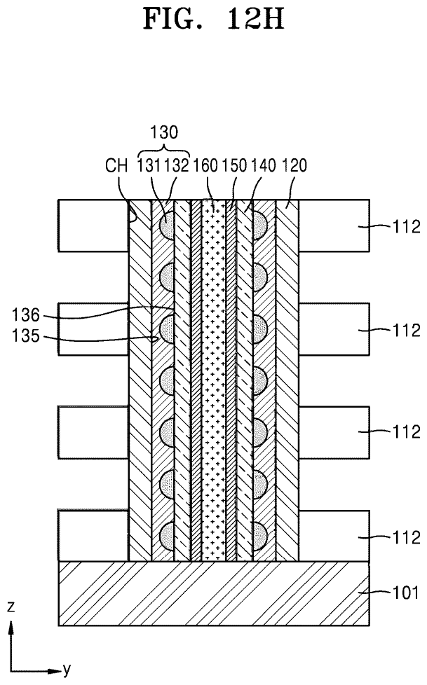

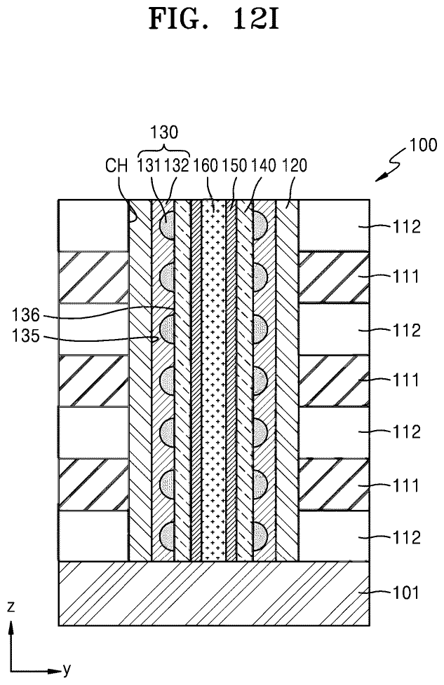

Next, a method of manufacturing a nonvolatile memory device, according to an example embodiment, is described with reference to FIGS. 12A to 12I.

Referring to FIG. 12A, spacers 112 and sacrificial layers 113 may be alternately stacked on a substrate 101. The spacers 112 may each include, for example, silicon oxide, silicon nitride, etc., but example embodiments of the present disclosure are not limited thereto. The spacers 112 may each include, for example, SiO₂. The sacrificial layers 113 may each include MO (where M is a metal), and M may include at least one of Hf, Ti, Zr, U, Th, Cr, Ga, V, Sc, Lu, Yb, Er, Ho, Dy, Gd, Eu, Sm, Y, Nd, Ce, La, Ni, Mg, Cu, Zn, Co, Fe, Mn, Ca, Eu, Sr, Sm, or Cu. The sacrificial layers 113 may each include, for example, HfO₂.

Referring to FIG. 12B, a channel hole CH may be formed to pass through the stack of the spacers 112 and the sacrificial layers 113. The channel hole CH may be formed to extend in a direction perpendicular to the surface of the substrate 101. The channel hole CH may be formed to have a circular cross-section. The channel hole CH may be formed by anisotropically etching the spacers 112 and the sacrificial layers 113.

Referring to FIG. 12C, a charge barrier layer 120 may be formed in the channel hole CH. The charge barrier layer 120 may be formed by chemical vapor deposition, physical vapor deposition, or atomic layer deposition.

Referring to FIG. 12D, a preliminary layer PL may be formed in the charge barrier layer 120. The preliminary layer PL may include an A material, a B material, and oxygen (O). The A material may include at least one of titanium (Ti), vanadium (V), hafnium (Hf), zirconium (Zr), cadmium (Cd), zinc (Zn), or chromium (Cr). The B material may include at least one of silicon (Si), aluminum (Al), or nitrogen (N). The preliminary layer PL may have a composition that includes AₓB_{y}O_{z} and satisfies 0.04≤x≤0.15, 0.16≤y≤0.30, 0.60≤z≤0.72, and x+y+z=1. For example, the preliminary layer PL may include TiSiO, wherein Ti may include a composition within a range of about 4 at % to about 15 at % and Si may include a composition within a range of about 16 at % to about 30 at %.

Referring to FIG. 12E, when the preliminary layer PL is heat-treated in a vacuum or gas atmosphere, phase separation may occur in the preliminary layer PL, and thus, the nanoparticles 131 and the matrix 132 may be formed. Consequently, a charge trap layer 130 including the nanoparticles 131 and the matrix 132 may be formed. The nanoparticles 131 and the matrix 132 may be formed simultaneously. The phase separation may be performed within a temperature range of about 900° C. to about 1,300° C. In some example embodiments, the phase separation may be performed within a temperature range of about 900° C. to about 1,100° C. The gas atmosphere may include nitrogen gas, argon gas, or oxygen. The phase separation may be performed by spinodal decomposition or a nucleation and growth process. The nanoparticles 131 may have a lower band gap than the matrix 132. The nanoparticles 131 may have lower surface energy than the matrix 132. The nanoparticles 131 may include at least one of titanium oxide, vanadium oxide, hafnium oxide, zirconium oxide, cadmium oxide, zinc oxide, or chromium oxide. The matrix 132 may include at least one of silicon oxide, silicon oxynitride, aluminum oxide, or aluminum oxynitride. When the preliminary layer PL includes TiSiO, the preliminary layer PL may be separated into TiO nanoparticles and a SiO matrix through heat treatment. When the preliminary layer PL includes HfSiO, the preliminary layer PL may be separated into HfO nanoparticles and a SiO matrix through heat treatment. Through temperature control, the nanoparticles 131 may be formed to come into contact with the second surface 136 and be spaced apart from the first surface 135. The nanoparticles 131 may have a shape protruding from the second surface 136 toward the first surface 135. The nanoparticles 131 may be spaced apart along the second surface 136 and arranged in a row. The nanoparticles 131 may act as charge storage particles, and the matrix 132 may support the nanoparticles 131 together with the function of insulating the nanoparticles 131 from each other.

Referring to FIG. 12F, a charge tunneling layer 140 may be formed in the charge trap layer 130. The charge tunneling layer 140 may be formed by physical vapor deposition, chemical vapor deposition, or atomic layer deposition. Referring to FIG. 12G, a channel layer 150 and a pillar 160 may be formed in the charge tunneling layer 140.

Referring to FIG. 12H, the sacrificial layers 113 may be removed. The sacrificial layers 113 may be removed by selective etching. Referring to FIG. 12I, gate electrodes 111 may be formed at positions where the sacrificial layers 113 have been removed. Consequently, a nonvolatile memory device 100 including the nanoparticles 131 may be manufactured.

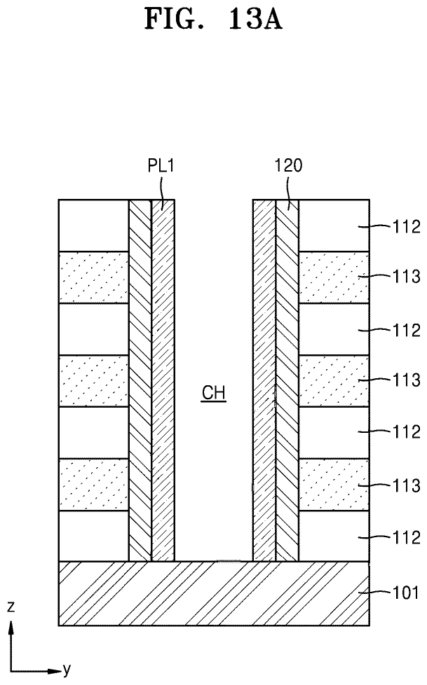

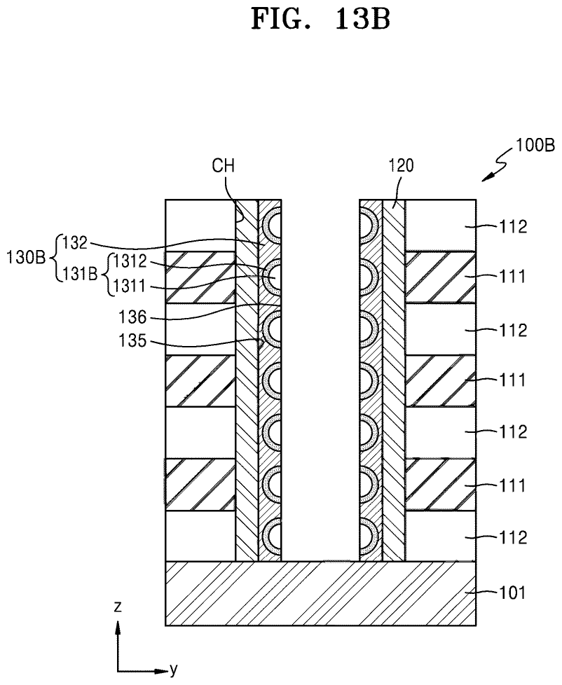

FIGS. 13A and 13B are diagrams for describing a method of forming nanoparticles having a core-shell structure.

Because FIG. 13A illustrates a structure formed by the same process as the process described with reference to 12D, a detailed description of the same process is omitted to avoid redundancy of explanation. Referring to FIG. 13A, a preliminary layer PL1 may be formed in or on the charge barrier layer 120. The preliminary layer PL may include an A material, a B material, a C material, and oxygen (O). The A material may include at least one of titanium (Ti), vanadium (V), hafnium (Hf), zirconium (Zr), cadmium (Cd), zinc (Zn), or chromium (Cr). The B material may include at least one of silicon (Si), aluminum (Al), or nitrogen (N). The C material may be a seed material and may include at least one of titanium (Ti), hafnium (Hf), zirconium (Zr), vanadium (V), cadmium (Cd), zinc (Zn), or chromium (Cr). The preliminary layer PL1 may have a composition that includes AₓB_{y}C_{w}O_{z} and satisfies 0.04≤x≤0.15, 0.16≤y≤0.30, 0.01≤w≤0.05, 0.60≤z≤0.72, x+y+w+z=1.

Referring to FIG. 13B, when the preliminary layer PL is heat-treated in a vacuum or gas atmosphere, phase separation may occur in the preliminary layer PL, and thus, the nanoparticles 131B and the matrix 132 may be formed. Consequently, a charge trap layer 130B including the nanoparticles 131B and the matrix 132 may be formed. The heat treatment may be performed within a temperature range of about 900° C. to about 1,100° C. The gas atmosphere may include nitrogen gas, argon gas, or oxygen. The phase separation may be performed by spinodal decomposition or a nucleation and growth process. The nanoparticles 131B may have a core-shell structure. The nanoparticles 131B may include a core 1311 and a shell 1312. The core 1311 may include a CO material or a C material, and the shell 1312 may include an AO material. The core 1311 may act as a seed to facilitate phase separation. The core 1311 may have a lower band gap and/or lower surface energy than the shell 1312. Because the processes after forming the charge trap layer 130B are the same as those in FIGS. 12F to 12I, a detailed description thereof is omitted herein.

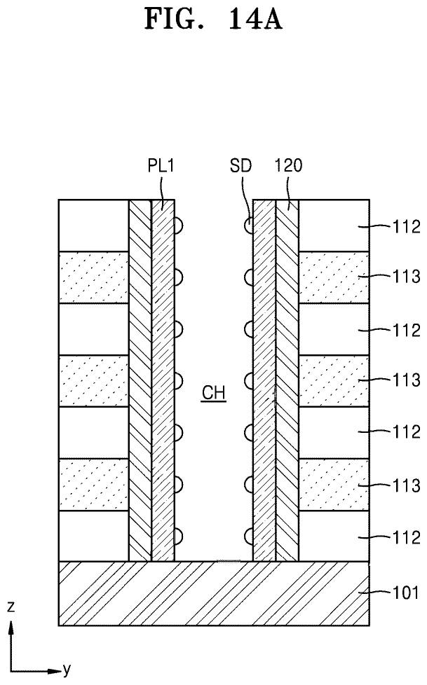

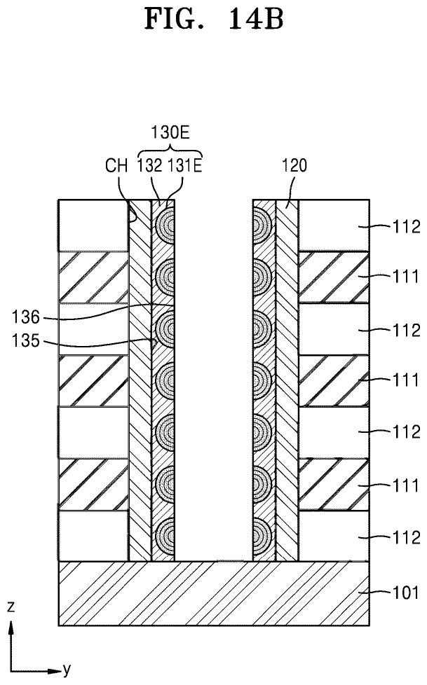

FIGS. 14A and 14B are diagrams for describing another method of forming nanoparticles.

Referring to FIG. 14A, after the preliminary layer PL1 is formed as described with reference to FIG. 13A, a seed layer SD may be formed on the preliminary layer PL1. The seed layer SD may be formed by atomic layer deposition or plasma enhanced chemical vapor deposition (PECVD). The seed layer SD may have a thickness greater than 0 nm and less than or equal to about 1 nm or may be formed in an island shape. The seed layer SD may include a C material or a CO material. The C material may include, for example, at least one of titanium (Ti), hafnium (Hf), zirconium (Zr), vanadium (V), cadmium (Cd), zinc (Zn), or chromium (Cr). The seed layer SD may promote phase separation of the preliminary layer PL1.

Referring to FIG. 14B, when the preliminary layer PL and the seed layer SD are heat-treated in a gas atmosphere, phase separation may occur in the preliminary layer PL, and thus, the nanoparticles 131E and the matrix 132 may be formed. Consequently, a charge trap layer 130E including the nanoparticles 131E and the matrix 132 may be formed. The nanoparticles 131E may have a gradation distribution in which a charge trap density varies. Because the processes after forming the charge trap layer 130E are the same as those in FIGS. 12F to 12I, a detailed description thereof is omitted herein.

As described above, in the nonvolatile memory devices 100, 100A, 100B, 100C, 100D, and 100E according to the above example embodiment, the charge trap layers 130, 130A, 130B, 130C, 130D, and 130E may be formed by using phase separation. The nonvolatile memory devices 100, 100A, 100B, 100C, 100D, and 100E according to the above example embodiment may have a relatively low operating voltage and/or a relatively large memory window due to the nanoparticles 131, 131A, 131B, 131C, 131D, and 131E. The nonvolatile memory devices 100, 100A, 100B, 100C, and 100D may be widely applied to mobile phones, digital cameras, PDAs, portable computing devices, etc.

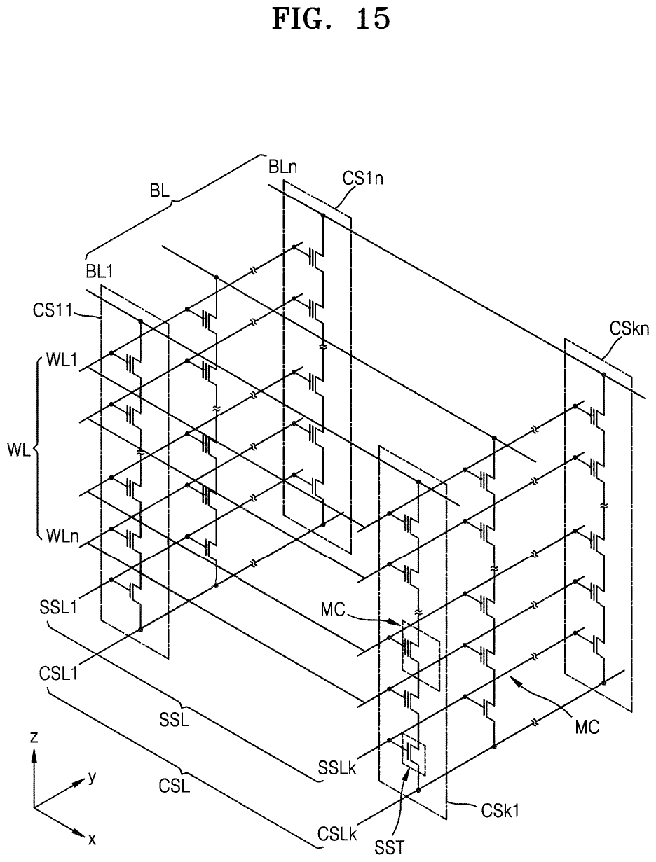

FIG. 15 illustrates a circuit diagram including a nonvolatile memory device according to an example embodiment. k*n cell strings may be arranged in a matrix form and may be denoted by CSij (1≤i≤k, 1≤j≤n) according to each row and column position. The cell strings CSij may each be connected to a bit line BL, a string select line SSL, a word line WL, and a common source line CSL.

The cell strings CSij may each include memory cells MC and a string select transistor SST. The memory cells MC and the string select transistor SST of each of the cell strings CSij may be stacked in the height direction.

The rows of the cell strings CSij may be connected to different string select lines SSL1 to SSLk, respectively. For example, the string select transistors SST of the cell strings CS11 to CS1n may be commonly connected to the string select line SSL1. The string select transistors SST of the cell strings CSk1 to CSkn may be commonly connected to the string select line SSLk.

The columns of the cell strings CS may be connected to different bit lines BL1 to BLn, respectively. For example, the memory cells MC and the string select transistors SST of the cell strings CS11 to CSk1 may be commonly connected to the bit line BL1, and the memory cells MC and the string select transistors SST of the cell strings CS1n to CSkn may be commonly connected to the bit line BLn.

The rows of the cell strings CS may be connected to different common source lines CSL1 to CSLk, respectively. For example, the string select transistors SST of the cell strings CS11 to CS1n may be commonly connected to the common source line CSL1, and the string select transistors SST of the cell strings CSk1 to CSkn may be commonly connected to the common source line CSLk.

The memory cells MC arranged at the same height from the substrate or the string select transistors SST may be commonly connected to one word line WL, and the memory cells MC arranged at different heights may be connected to different word lines WL1 to WLn, respectively.

The illustrated circuit structure is only an example. For example, the number of rows of the cell strings CS may be increased or decreased. As the number of rows of the cell strings CS changes, the number of string select lines connected to the rows of the cell strings CS and the number of cell strings CS connected to one bit line BL may also change. As the number of rows of the cell strings CS changes, the number of common source lines connecting the rows of the cell strings CS may also change.

The number of columns of the cell strings CS may also be increased or decreased. As the number of columns of the cell strings CS changes, the number of bit lines BL connected to the columns of the cell strings CS and the number of cell strings CS connected to one string select line may also change.

The heights of the cell strings CS may also be increased or decreased. For example, the number of memory cells MC stacked in each of the cell strings CS may be increased or decreased. As the number of memory cells MC stacked in each of the cell strings CS changes, the number of word lines WL may also change. For example, the string select transistors SST respectively provided to the cell strings CS may be increased. As the number of string select transistors SST respectively provided to the cell strings CS changes, the number of string select lines or common source lines may also change. When the number of string select transistors SST is increased, the string select transistors SST may be stacked in the same form as the memory cells MC.

For example, write and read operations may be performed in units of the rows of the cell strings CS. The cell strings CS may be selected in units of a single row by the common source line CSL, and the cell strings CS may be selected in units of a single row by the string select lines SSL. In addition, a voltage may be applied to the common source lines CSL, with at least two common source lines CSL as a single unit. In some example embodiments, a voltage may be applied to the common source lines CSL, with the entire common source lines as a single unit.

In the selected row of the cell strings CS, the write and read operations may be performed in units of pages. The page may be a single row of memory cells connected to a single word line WL. In the selected row of the cell strings CS, the memory cells may be selected by the word lines WL in units of pages. For example, the gate electrodes 111 of FIG. 1 may each be connected to one of the word line WL or the string select line SSL.

The memory cell MC may have a circuit structure in which the transistor including the gate electrode 111, the spacer 112, and the channel layer 150 is connected to the charge trap layer 130.

The memory cells MC may be arranged sequentially in a vertical direction (a Z direction) to constitute the cell string CS. Both ends of the cell string CS may be connected to the common source line CSL and the bit line BL, respectively, as illustrated in the circuit diagram of FIG. 15. By applying a voltage to the common source line CSL and the bit line BL, program, read, and erase operations may be performed on the memory cells MC.

For example, when a memory cell MC to be written is selected, a gate voltage value of the selected memory cell may be adjusted so that a channel is not formed in the selected memory cell (e.g., the channel is turned off), and gate voltage values of the unselected memory cells may be adjusted so that channels of the unselected memory cells are turned on. Charges may tunnel through the charge tunneling layer 140 due to the voltage applied to the common source line CSL and the bit line BL and may be stored in the charge trap layer 130 of the selected memory cell MC. Accordingly, information of 1 or 0 may be recorded in the selected memory cell MC.

Similarly, the read operation may be performed on the selected memory cell MC. That is, the gate voltage applied to each gate electrode 111 may be adjusted so that the channel of the selected memory cell MC is turned off and the channels of the unselected memory cells are turned on, and then, a memory cell state (1 or 0) may be identified by measuring a current flowing to the corresponding memory cell MC by a voltage (Vread) applied between the common source line CSL and the bit line BL.

The nonvolatile memory devices 100, 100A, 100B, 100C, 100D, and 100E according to an example embodiment may be applied to various electronic apparatuses.

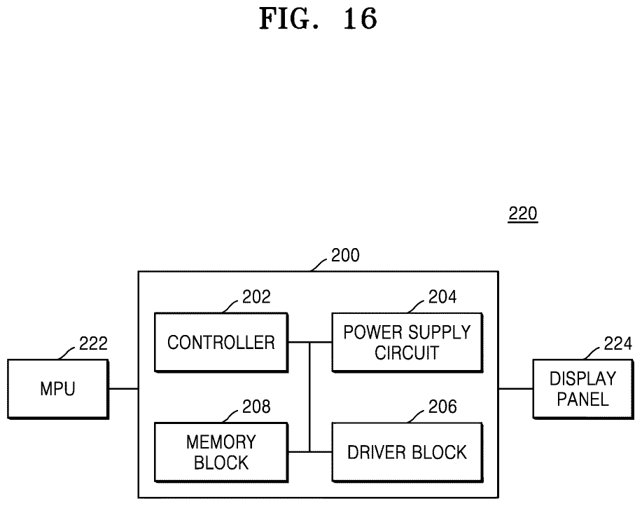

FIG. 16 is a schematic block diagram of a display device 220 including a display driver integrated circuit (IC) (DDI) 200, according to an example embodiment. Referring to FIG. 16, the DDI 200 may include a controller 202, a power supply circuit 204, a driver block 206, and a memory block 208. The controller 202 may receive and decode a command applied from a main processing unit (MPU) 222 and may control each block of the DDI 200 to implement an operation according to the command. The power supply circuit 204 may generate a driving voltage in response to the control by the controller 202. The driver block 206 may drive the display panel 224 by using the driving voltage generated by the power supply circuit 204 in response to the control by the controller 202. The display panel 224 may be, for example, a liquid crystal display panel, an organic light-emitting device (OLED) display panel, or a plasma display panel. The memory block 208 is a block that temporarily stores commands input to the controller 202 or control signals output from the controller 202 or stores necessary or desired data. The memory block 208 may include a memory such as random access memory (RAM) or read-only memory (ROM). For example, the memory block 208 may include the nonvolatile memory devices 100, 100A, 100B, 100C, 100D, and 100E according to the example embodiments described above.

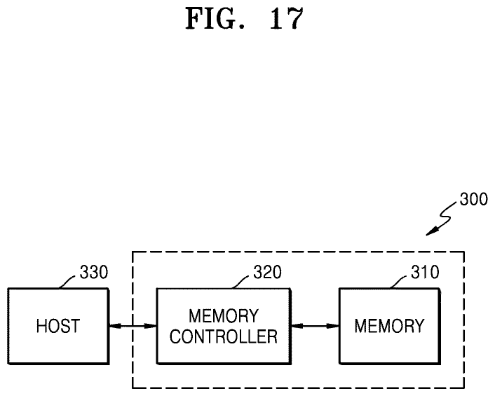

FIG. 17 is a block diagram of an electronic apparatus 300 according to an example embodiment. Referring to FIG. 17, the electronic apparatus 300 may include a memory 310 and a memory controller 320. The memory controller 320 may control the memory 310 to read data from and/or write data to the memory 310 in response to a request from a host 330. The memory 310 may include the nonvolatile memory devices 100, 100A, 100B, 100C, 100D, and 100E according to the example embodiments described above.

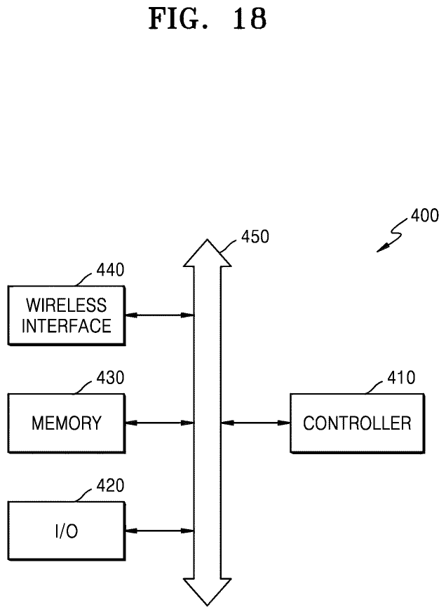

FIG. 18 is a block diagram of an electronic apparatus 400 according to an example embodiment. Referring to FIG. 18, the electronic apparatus 400 may constitute a wireless communication device or a device capable of transmitting and/or receiving information in a wireless environment. The electronic apparatus 400 may include a controller 410, an input/output (I/O) device 420, a memory 430, and a wireless interface 440, and these components maybe interconnected to each other through a bus 450.

The controller 410 may include at least one of a microprocessor, a digital signal processor, or a processing device similar thereto. The I/O device 420 may include at least one of a keypad, a keyboard, or a display. The memory 430 may be used to store commands executed by controller 410. For example, the memory 430 may be used to store user data. The electronic apparatus 400 may use the wireless interface 440 to transmit/receive data through a wireless communication network. The wireless interface 440 may include an antenna and/or a wireless transceiver. In some example embodiments, the electronic apparatus 400 may be used in a communication interface protocol of a third-generation communication system, for example, code division multiple access (CDMA), global system for mobile communications (GSM), north American digital cellular (NADC), extended-time division multiple access (E-TDMA), and/or wide band code division multiple access (WCDMA). The memory 430 of the electronic apparatus 400 may include the nonvolatile memory devices 100, 100A, 100B, 100C, 100D, and 100E according to the example embodiments described above.

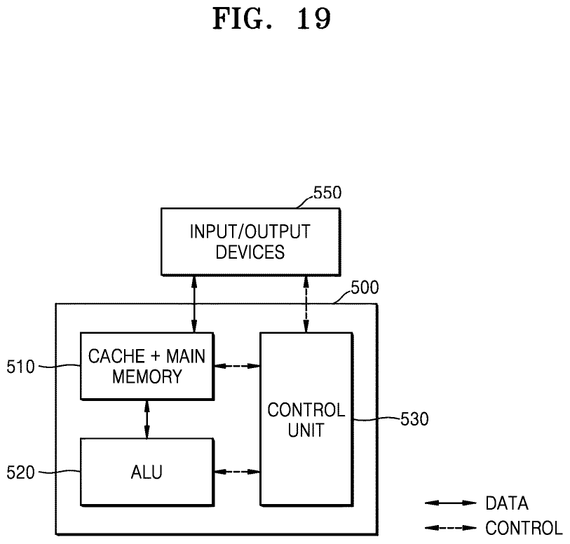

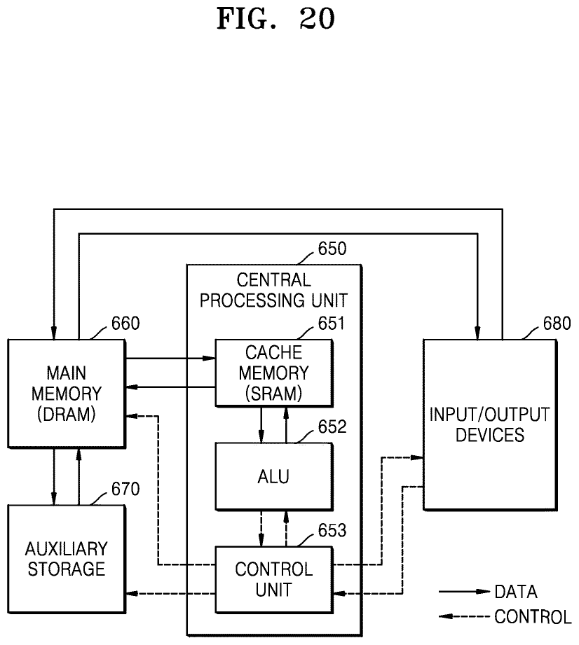

FIGS. 19 and 20 are conceptual diagrams schematically illustrating an electronic element architecture 500 applicable to an electronic apparatus according to an example embodiment.

Referring to FIG. 19, the electronic element architecture 500 may include a memory unit 510 and a control unit 530 and may further include an arithmetic logic unit (ALU) 520. The memory unit 510, the ALU 520, and the control unit 530 may be electrically connected to each other. For example, the electronic element architecture 500 may be implemented as a single chip including the memory unit 510, the ALU 520, and the control unit 530. For example, the memory unit 510, the ALU 520, and the control unit 530 may be interconnected in an on-chip manner via a metal line to perform direct communication. The memory unit 510, the ALU 520, and the control unit 530 may be monolithically integrated on a single substrate (see 101 of FIG. 1) to constitute a single chip. I/O devices 550 may be connected to the electronic element architecture 500. In addition, the memory unit 510 may include both a main memory and a cache memory. The electronic element architecture 500 may be an on-chip memory processing unit. The memory unit 510, the ALU 520, and/or the control unit 530 may each independently include the nonvolatile memory devices 100, 100A, 100B, 100C, 100D, and 100E according to the example embodiments described above.

Referring to FIG. 20, a cache memory 651, an ALU 652, and a control unit 653 may constitute a central processing unit (CPU) 650. The cache memory 651 may include static random access memory (SRAM). Separately from the CPU 650, a main memory 660 and an auxiliary storage 670 may be provided, and I/O devices 680 may be further provided. The main memory 660 may include the nonvolatile memory devices 100, 100A, 100B, 100C, 100D, and 100E according to the example embodiments described above.

In some cases, the device architecture may be implemented in a form in which computing unit elements and memory unit elements are adjacent to each other on a single chip, without distinction of sub-units.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Nonvolatile memory devices according to some example embodiments may be applied to various user devices, such as a computer, a mobile computer, an ultra-mobile personal computer (UMPC), a workstation, a netbook, a PDA, a portable computer, a web tablet, a wireless phone, a mobile phone, a smartphone, a digital camera, a digital audio recorder, a digital audio player, a digital picture recorder, a digital picture player, a digital video recorder, a digital video player, a device capable of transmitting and receiving information in a wireless environment, or a home network.

Nonvolatile memory devices according to some example embodiments may widen a memory window and/or lower an operating voltage by including nanoparticles in the charge trap layer. Therefore, a relatively high-density and/or relatively low-power nonvolatile memory device may be provided. In the nonvolatile memory device according to some example embodiments, electrons may be stored in the structurally isolated nanoparticles, and thus, lateral charge loss may be effectively reduced.

Methods of manufacturing a nonvolatile memory device, according to some example embodiments, may form nanoparticles through phase separation in the charge trap layer.

It should be understood that some example embodiments described herein should be considered in a descriptive sense only and not for purposes of limitation. Descriptions of features or aspects within each example embodiment should typically be considered as available for other similar features or aspects in other example embodiments. While one or more example embodiments have been described with reference to the figures, it will be understood by those of ordinary skill in the art that various changes in form and details may be made therein without departing from the spirit and scope as defined by the following claims.

What is claimed is:

1. A nonvolatile memory device comprising:
a gate stack comprising gate electrodes and spacers, the gate electrodes and the spacers being alternately stacked on each other;
a channel hole passing through the gate stack;
a charge trap layer in the channel hole;
a charge tunneling layer in the charge trap layer; and
a channel layer in the charge tunneling layer,
wherein the charge trap layer comprises a first surface facing the gate stack and a second surface facing the channel layer,
the charge trap layer comprises nanoparticles and a matrix supporting the nanoparticles, and
the nanoparticles are spaced apart from the first surface and come into contact with the second surface.

2. The nonvolatile memory device of claim 1, wherein the nanoparticles have a shape that protrudes convexly from the second surface toward the first surface.

3. The nonvolatile memory device of claim 1, wherein the nanoparticles have a shape in which a width changes as a distance from the second surface increases.

4. The nonvolatile memory device of claim 1, wherein an area of a surface where the nanoparticles come into contact with the charge tunneling layer is less than an area of a surface where the nanoparticles do not come into contact with the charge tunneling layer.

5. The nonvolatile memory device of claim 1, wherein an area of a surface where the matrix comes into contact with the charge tunneling layer is less than an area of a surface where the matrix does not come into contact with the charge tunneling layer.

6. The nonvolatile memory device of claim 1, wherein an area of a surface where the nanoparticles come into contact with the charge tunneling layer is greater than an area of a surface where the matrix comes into contact with the charge tunneling layer.

7. The nonvolatile memory device of claim 1, wherein a maximum width of a surface where the nanoparticles come into contact with the charge tunneling layer is within a range of 2 nm to 10 nm.

8. The nonvolatile memory device of claim 1, wherein the nanoparticles comprise a material having a lower band gap than the matrix and lower surface energy than the matrix.

9. The nonvolatile memory device of claim 1, wherein the nanoparticles comprise at least one of titanium oxide, vanadium oxide, hafnium oxide, zirconium oxide, cadmium oxide, zinc oxide, or chromium oxide.

10. The nonvolatile memory device of claim 1, wherein the matrix comprises at least one of silicon oxide, silicon oxynitride, aluminum oxide, or aluminum oxynitride.

11. An electronic apparatus comprising:
a memory device; and
a memory controller configured to control the memory device to perform at least one of reading data from the memory device or writing data to the memory device,
wherein the memory device comprises
a gate stack comprising gate electrodes and spacers, the gate electrodes and the spacers being alternately stacked on each other,
a channel hole passing through the gate stack,
a charge trap layer in the channel hole,
a charge tunneling layer in the charge trap layer, and
a channel layer in the charge tunneling layer, and
wherein the charge trap layer comprises a first surface facing the gate stack and a second surface facing the channel layer,
the charge trap layer comprises nanoparticles and a matrix supporting the nanoparticles, and
the nanoparticles are spaced apart from the first surface and come into contact with the second surface.

12. The electronic apparatus of claim 11, wherein the nanoparticles have a shape that protrudes convexly from the second surface toward the first surface.

13. The electronic apparatus of claim 11, wherein the nanoparticles have a shape in which a width changes as a distance from the second surface increases.

14. The electronic apparatus of claim 11, wherein an area of a surface where the nanoparticles come into contact with the charge tunneling layer is less than an area of a surface where the nanoparticles do not come into contact with the charge tunneling layer.

15. The electronic apparatus of claim 11, wherein a maximum width of a surface where the nanoparticles come into contact with the charge tunneling layer is within a range of 2 nm to 10 nm.

16. The electronic apparatus of claim 11, wherein the nanoparticles comprise at least one of titanium oxide, vanadium oxide, hafnium oxide, zirconium oxide, cadmium oxide, zinc oxide, or chromium oxide.

17. The electronic apparatus of claim 11, wherein the matrix comprises at least one of silicon oxide, silicon oxynitride, aluminum oxide, or aluminum oxynitride.

18. A method of manufacturing a nonvolatile memory device, the method comprising:
alternately stacking spacers and sacrificial layers on a substrate;
forming a channel hole to pass through the spacers and the sacrificial layers;
forming a preliminary layer inside the channel hole;
forming a charge trap layer by phase separation into nanoparticles and a matrix through heat treatment on the preliminary layer;
forming a charge tunneling layer in the charge trap layer;
forming a channel layer in the charge tunneling layer;
removing the sacrificial layers; and
forming gate electrodes at positions where the sacrificial layers have been removed,
wherein the charge trap layer comprises a first surface facing the gate electrodes and a second surface facing the channel layer, and
the nanoparticles are spaced apart from the first surface and come into contact with the second surface.

19. The method of claim 18, wherein the forming the charge trap layer forms the nanoparticles and the matrix simultaneously by performing the phase separation within a temperature range of 900° C. to 1,300° C.

20. The method of claim 18, wherein the nanoparticles comprise at least one of titanium oxide, vanadium oxide, hafnium oxide, zirconium oxide, cadmium oxide, zinc oxide, or chromium oxide.
